(19) United States
(12) Patent Application Publication
(10) Pub. No.: US 2012/0300525 A1
(43) Pub. Date: Nov. 29, 2012

(54) CONVERTER ARRANGEMENT AND METHOD IN CONNECTION WITH CONVERTER ARRANGEMENT

(75) Inventors: Timo Koivuluoma, Vantaa (FI); Kari Kovanen, Espoo (FI); Juhani Helosvouri, Riihimaki (FI)

(73) Assignee: ABB Oy, Helsinki (FI)

(21) Appl. No.: 13/482,276

(22) Filed: May 29, 2012

(30) Foreign Application Priority Data
May 27, 2011 (EP) 11167886.8

(51) Int. Cl. H05K 7/20

(52) U.S. Cl. 363/141

(57) ABSTRACT

An exemplary converter arrangement and method in connection with the arrangement includes a converter arranged in a closed container or similar structure. The container has a high voltage compartment and a low voltage compartment. The high voltage compartment includes a transformer connectable to a network to be supplied and the low voltage compartment includes the converter. The arrangement being configured to exchange heat from the high voltage compartment to the low voltage compartment and heating the low voltage compartment with losses of the transformer.

### RELATED APPLICATION

This application claims priority under 35 U.S.C. §119 to European Patent Application No. 11167886.8 filed in Europe on May 27, 2011, the content of which is hereby incorporated by reference in its entirety.

### FIELD

The present disclosure relates to a converter, such as a converter arrangement in a container structure containing at least some of the electrical components of the converter, and more particularly to a container structure in which the indoor climate is controlled.

### BACKGROUND INFORMATION

Known converters are used in many applications for converting electrical energy from one form to another. Converters are used for example in connection with wind power and solar power. In solar power applications, a converter receives DC voltage from photovoltaic panels and converts it to AC voltage. AC voltage is further fed to the network. In some applications, a transformer is also used between the converter and the network. In solar power applications, the converter used for converting the voltage is also called a solar inverter.

In wind power applications, a converter receives electrical power from a rotating generator. The power from the generator is AC power, and the converter changes the frequency and the amplitude of the power such that it can be fed to the grid. As in connection with solar inverters, a transformer is often employed between the converter and the grid.

Converters or inverters needed in solar and wind power applications can be placed in containers or similar simple enclosures. These containers are then placed near the actual power generation points. These containers are thus located outdoors in the fields or open places which are suitable for the generation of power. The containers or enclosures and the electric components inside the enclosures are cooled using heat exchangers or directly with air from outside the enclosure.

For natural reasons, the solar inverter operates cyclically. In the daytime, the inverter is in operation, feeding power to the grid. When the sun sets or when the solar panels are not able to generate enough power, the inverter is switched off completely. Also in connection with wind power, the converter supplying the grid is switched off whenever the wind speed is not high enough or is so high that generation of wind power is impossible.

The cyclic operation of the converter causes problems relating to temperature and humidity inside the enclosure. The temperature inside the enclosure varies considerably and the repeated changes in the temperature cause the semiconductor components to wear out prematurely. Further, the humidity inside the container may cause short circuits. The condensed water may also freeze inside the container, which may block the operation of the converter completely.

It is common to use blowers to blow air through the container and the electrical components. The air inside gets cooler as the outside temperature decreases. If humidity is not filtered off the inlet air, the humidity from the air ends up inside the container.

If heat exchangers are used in a traditional way, the heat exchangers transfer heat whenever the outside temperature is lower than the temperature inside the container and a constant amount of air is blown through the exchanger. Owing to changes in the outside temperature, the temperature inside the container varies and the semiconductor lifetime becomes shorter.

If the inside air contains humidity, the air may condensate without control in a wrong place. Since containers are not airtight, wet air easily passes inside the containers and the condensed water causes problems which may lead to total breakage of the system.

In very harsh conditions, the temperature inside the container may drop considerably below zero degrees Celsius. Normal electronic components are not specified at temperatures which are near −20° C. It is possible that the equipment does not start or it may become damaged owing to the temperature. In such a case, heating is specified inside the container for keeping the temperature within allowed limits.

### SUMMARY

An exemplary converter arrangement is disclosed, comprising: a converter in a closed container, the container having at least two compartments, the compartments including a high voltage compartment and a low voltage compartment, wherein the high voltage compartment includes a transformer connectable to a network to be supplied and the low voltage compartment includes the converter; and means for exchanging heat from the high voltage compartment to the low voltage compartment and for heating the low voltage compartment with losses of the transformer.

An exemplary method in connection with a converter arrangement is disclosed, the arrangement having a converter in a closed container, the container having a high voltage compartment and a low voltage compartment, wherein the high voltage compartment includes a transformer connected to a network to be supplied and the low voltage compartment includes the converter, the method comprising: exchanging heat from the high voltage compartment to the low voltage compartment for heating the low voltage compartment with losses of the transformer.

A converter arrangement is disclosed, comprising: a converter disposed in a closed container, wherein the container includes a high voltage compartment and a low voltage compartment arranged to exchange heat therebetween, and wherein the high voltage compartment has a transformer connectable to a network to be supplied and the low voltage compartment includes the converter.

### BRIEF DESCRIPTION OF THE DRAWINGS

In the following, the disclosure will be described in greater detail by means of exemplary embodiments and with reference to the accompanying drawings, in which

FIG. 1 shows a block diagram of a photovoltaic power generation system in accordance with an exemplary embodiment of the present disclosure;

FIG. 2 shows a cross section of a container having an arrangement in accordance with an exemplary embodiment of the present disclosure; and

FIG. 3 shows an arrangement of a container in accordance with an exemplary embodiment of the present disclosure.

### DETAILED DESCRIPTION

Exemplary embodiments of the present disclosure provide a method and an arrangement for implementing the method to overcome the above problem.

Exemplary embodiments disclosed herein use losses of a transformer in heating electrical parts of a converter situated in a container or a similar structure. The transformer, which feeds power to a network, is not separated from the network although it is not feeding power. The transformer is situated inside the container, but since it is a high-voltage device, it is kept in a completely closed part inside the container. This part of the container is closed in such a manner that only a very limited number of service personnel may enter this part owing to safety regulations.

The losses of a high-voltage or medium-voltage transformer keep the transformer warm, and this heat is transferred in the container to the part in which the inverter equipment is situated.

An advantage of the exemplary method and arrangement of the disclosure is that the temperature cycling can be minimized with a very cost effective and a passive solution. Due to reduced temperature cycling, the expected life times of semiconductor components in the converter structure are longer. Further, since the temperature can be kept at a higher level, the problem relating to humidity is greatly alleviated.

According to an exemplary embodiment, for further minimizing the temperature cycling, the heat is stored inside the container in the structures of the converter by raising the temperature during the operation of the converter.

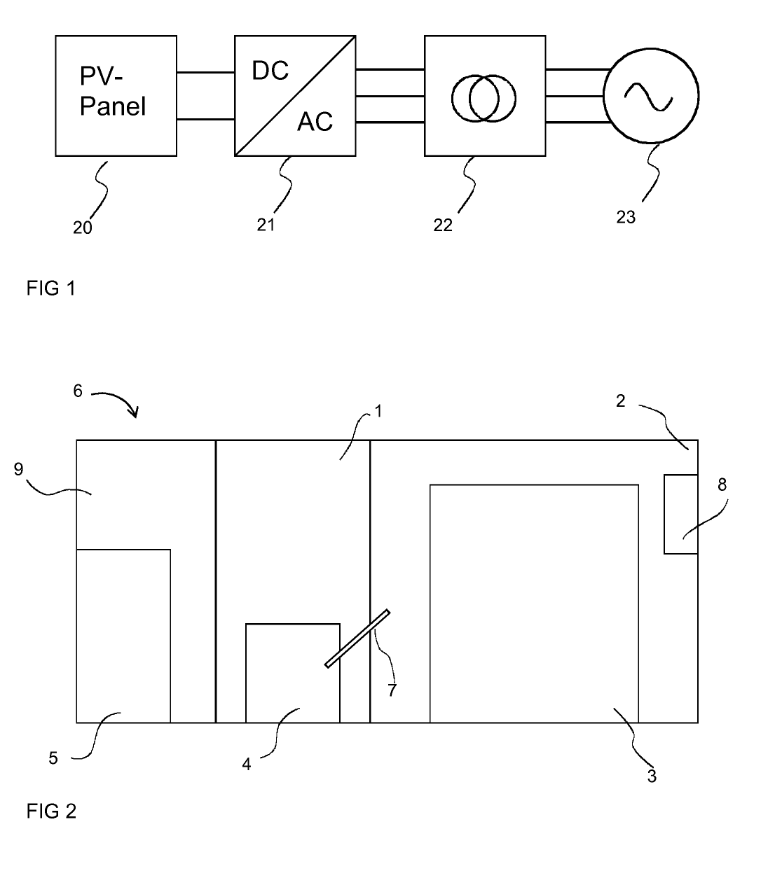

FIG. 1 shows a block diagram of a photovoltaic power generation system in accordance with an exemplary embodiment of the present disclosure. As shown in FIG. 1, a photovoltaic panel, string, or array of such panels 20 produces a DC voltage and provides it to a converter 21. A converter is an inverter having possibly multiple converting stages, and in connection with solar power, the converter is often called a solar inverter. The purpose of this converter is to produce AC voltage from the DC voltage obtainable from the solar panel 20. The AC voltage is produced such that its phase and frequency are synchronized with the voltage of a supplied network 23. In an exemplary arrangement of the present disclosure, a transformer 22 is used for raising the voltage level of the voltage produced with the converter 22. The transformer is further connected to the transmission network for feeding the generated power to the network.

Usually the high voltage transformers are not disconnected from the network although no power is fed through the transformer to the network. FIG. 2 shows a cross section of a container having an arrangement in accordance with an exemplary embodiment of the present disclosure. Decoupling of the transformer from the network is a rough operation, producing arcing, and wearing down the components dramatically. The switches have a limited number of disconnections which they can withstand. Although no current is flowing through the transformer, the transformer has some losses which keep the transformer warm. These no-load losses mainly include (e.g., consist of) hysteresis and eddy-current losses.

Usually the transformer is cooled down by using cooling fins, and the transformer can run at quite a high temperature since it does not have any components that are very sensitive to heat. FIG. 2 shows a cross section of a container having an arrangement in accordance with an exemplary embodiment of the present disclosure. In the exemplary arrangement, a container or a similar closed structure 6 is divided into sections or compartments. A transformer 4 is in one of the compartments 1 and a converter 3 is in another compartment 2. The transformer can be located in a separate closed section to comply with safety regulations, according to which access to high voltage components is restricted. FIG. 2 shows another compartment 5 inside the container in which some control electronics and switchgear is situated.

As the transformer is enclosed in the compartment 1, the converter is situated in the compartment 2. The converter and the transformer are naturally electrically connected for feeding power from the converter to the transformer. Further, the transformer 4 is electrically connectable to the transmission network.

According to an exemplary embodiment of the present disclosure, the arrangement comprises means for exchanging heat from a high voltage compartment to a low voltage compartment. The purpose of the exchange of heat is to warm the converter structure with the losses of the transformer when the converter is not in operation or is operated with a low load such that the converter is not heating itself.

According to another exemplary embodiment, the means for exchanging heat comprises a hatch that can be opened and closed in a controlled manner, and a blower for moving warm air from the high voltage compartment to the low voltage compartment. The hatch can be opened, for example, depending on the temperature of the low voltage compartment or because of a difference between outside and inside temperature of the low voltage compartment. Once the temperature of the low voltage compartment decreases and gets closer to the outside temperature, the hatch is opened and heat from the high voltage compartment is transferred to the low voltage side. If the temperature of the low voltage side can be kept higher than that of the dew point, the humidity should not condense inside the container.

According to another exemplary embodiment, the means for exchanging heat comprises a heat exchanger which is especially a thermosyphon-type heat exchanger. An example of this type of heat exchanger is a heat pipe in which liquid in a pipe-like structure evaporates owing to heat and condenses back to liquid, releasing heat. As is well known, these type of heat exchangers are passive and do not call for any energy for the operation. However, the efficiency of the heat exchange increases greatly if a small blower is used for circulating air when the heat is released from the tube. Further, the blower circulates the air in the low voltage compartment and thereby the heat is more evenly distributed. Another example of a thermosyphon-type heat exchanger is presented in EP 2031332 A1.

FIG. 2 also shows how a heat exchanger 7 is situated. A bottom end of the exchanger, such as a heat pipe, is physically connected to a heat source, which in the case of exemplary embodiments disclosed herein is the transformer 4. One end of the pipe may be wedged between the cooling fins of the transformer. The cooling fins may be in a form of corrugated metal sheet. When the liquid in the exchanger warms up, it evaporates and travels to the other end of the exchanger. When in the other end, the vapor releases heat and condenses back to liquid. As can be seen, the exchanger goes through a wall between the high voltage and low voltage compartments.

When heating of the low voltage compartment is specified, the passive exchanger starts operation by itself. In fact, the operation is continuous since the surface of the transformer is warmer than the air in the low voltage compartment even if the converter is in operation. When a blower is used inside the low voltage compartment for enhancing heat transfer, the blower can simply be turned on when the converter is shut down. Exemplary embodiments can use heat exchangers that do not move air from one compartment to another, since it is more energy efficient and since the air in the high voltage compartment may contain impurities that are not desirable in the low voltage compartment. If the air is highly polluted, it may even disturb the operation of the converter.

The amount of heat transfer can be increased by increasing the number of heat exchangers. Since, for example, a heat pipe is merely put into contact with the surface of the transformer, the number of such pipes can be increased easily. The heat pipe does not affect the cooling of the transformer itself. A 1 MW transformer has no-load losses that are in the range of 6 kW, and only a portion of this power is enough to keep the temperature of the low voltage side at an elevated level.

The temperature cycling can be further reduced by using the thermal masses of the converter structure to store heat. This means that the converter is operated at an elevated temperature at least before the shut down, so that heat is stored in the mechanical structures. A converter structure provided in a container may have a mass of 4000 kg. When this mass is heated, it will keep itself warm overnight. The heat may be gathered in the mass by decreasing the cooling of the converter compartment. When the converter is operated, it is cooled with cooling means 8 from the outside air. The cooling means may comprise blowers and hatches, which can be controlled to elevate the temperature to a higher level. It should be noted, however, that the temperature of the converter should not exceed the safe operating temperatures. The cooling means 8 may also be a heat exchanger with a blower. In such a case, no air from the outside of the container is used in the cooling.

The thermal mass can be heated with heat from the transformer by using heat pipes or similar structures. The thermal mass to be heated is situated higher than the end of the heat pipe that is in connection with the transformer. The heat from the transformer is transferred effectively and it keeps the thermal mass at an elevated temperature.

According to an exemplary embodiment, the arrangement further comprises a phase change material that is added into the container in the low voltage compartment. The phase change material (PCM) is added to act as thermal mass that is heated to an elevated temperature. Each PCM material has a certain phase change temperature. When this temperature is reached, the material starts changing its phase, keeping the temperature at the same level.

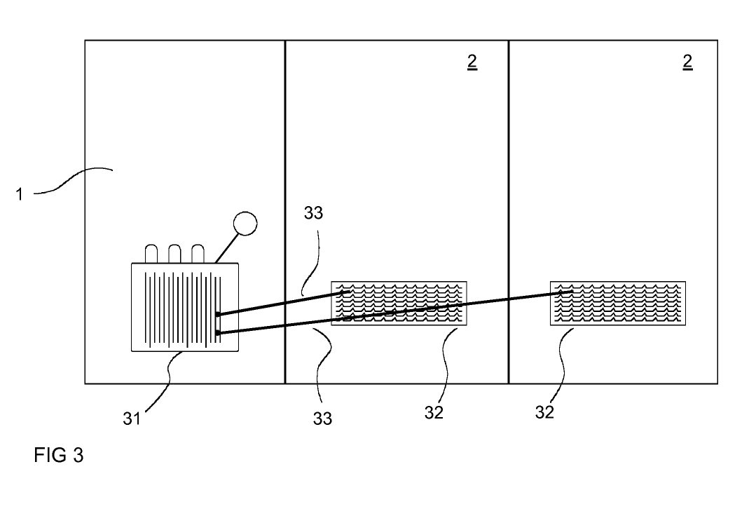

FIG. 3 shows an arrangement of a container in accordance with an exemplary embodiment of the present disclosure. As shown in FIG. 3, the container is divided into three sections or compartments. A compartment 1 includes a transformer 31 and compartments 2 both include parts of the converter. FIG. 3 schematically shows how the heat pipes or similar thermosyphon-like devices can be used for carrying heat to spaces that are located substantially far away from the source of heat. In the exemplary embodiment of FIG. 3, heat pipes 33 are transferring heat to enclosures 2 that are side by side. The bottom end of the heat pipes is connected to the transformer 31, and the other ends are placed inside separate compartments of the container. Fans 32 or blowers are placed in the compartments 2 for removing the heat from the pipes more efficiently and at the same time for heating the devices in the compartments.

In another exemplary embodiment of the disclosure, the heat from the transformer is transferred to the other compartments by using a heat exchanger with liquid circulation. The circulated liquid stores the heat from the transformer and the heat is delivered to the compartment with the converter. The heat transfer is effectively controlled using a small pump for controlling the flow of liquid in the system. In order to deliver the heat in a more effective way, the heat exchanger includes a radiator such that the heat from the liquid is transferred faster to the air inside the compartment.

According to an exemplary method of the present disclosure, the method in connection with the converter arrangement comprises a step of using the heat produced by the transformer in the heating of a separate compartment of the container. The heat can be used by transferring air from the compartment having the transformer or by using a heat exchanger for exchanging the heat to the low voltage compartment.

The exemplary embodiments provided herein are described in connection with solar power, the container incorporating the power electronic devices specified for extracting the power from the panel and converting the obtained voltage to a three phase voltage for inputting it to a transformer. The disclosure is not limited to solar systems, but may also be used in connection with wind power and any other possible energy system in which the converter structures are placed in a container together with a transformer.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A converter arrangement, comprising:
a converter in a closed container, the container having at least two compartments, the compartments including a high voltage compartment and a low voltage compartment, wherein the high voltage compartment includes a transformer connectable to a network to be supplied and the low voltage compartment includes the converter; and
means for exchanging heat from the high voltage compartment to the low voltage compartment and for heating the low voltage compartment with losses of the transformer.

2. The arrangement according to claim 1, wherein the means for exchanging heat from the high voltage compartment to the low voltage compartment are adapted to transfer heat when the converter in the low voltage compartment is not operating or is operated with a low load.

3. The arrangement according to claim 1, wherein the means for exchanging the heat comprise a hatch separating the compartments and a blower for transferring air from the high voltage compartment to the low voltage compartment.

4. The arrangement according to claim 1, wherein the means for exchanging the heat comprise a thermosyphon-type heat exchanger, such as a heat pipe, which is thermally connected to a surface of the transformer and which extends to the low voltage compartment for heating the low voltage compartment.

5. The arrangement according to claim 1, wherein the low voltage compartment comprises controlled cooling means, control of which being adapted to keep the temperature of the converter at an elevated level for storing heat in the mechanical structure of the converter.

6. The arrangement according to claim 1, wherein the low voltage compartment comprises additional thermal mass or phase change materials, for storing the heat in the low voltage compartment.

7. The arrangement according to claim 2, wherein the means for exchanging the heat comprise a hatch separating the compartments and a blower for transferring air from the high voltage compartment to the low voltage compartment.

8. The arrangement according to claim 2, wherein the means for exchanging the heat comprise a thermosyphon-type heat exchanger, such as a heat pipe, which is thermally connected to a surface of the transformer and which extends to the low voltage compartment for heating the low voltage compartment.

9. The arrangement according to claim 2, wherein the low voltage compartment comprises controlled cooling means, control of which being adapted to keep the temperature of the converter at an elevated level for storing heat in the mechanical structure of the converter.

10. The arrangement according to claim 2, wherein the low voltage compartment comprises additional thermal mass or phase change materials, for storing the heat in the low voltage compartment.

11. The arrangement according to claim 3, wherein the low voltage compartment comprises controlled cooling means, control of which being adapted to keep the temperature of the converter at an elevated level for storing heat in the mechanical structure of the converter.

12. The arrangement according to claim 3, wherein the low voltage compartment comprises additional thermal mass or phase change materials, for storing the heat in the low voltage compartment.

13. The arrangement according to claim 4, wherein the low voltage compartment comprises controlled cooling means, control of which being adapted to keep the temperature of the converter at an elevated level for storing heat in the mechanical structure of the converter.

14. The arrangement according to claim 4, wherein the low voltage compartment comprises additional thermal mass or phase change materials, for storing the heat in the low voltage compartment.

15. The arrangement according to claim 5, wherein the low voltage compartment comprises additional thermal mass or phase change materials, for storing the heat in the low voltage compartment.

16. A method in connection with a converter arrangement, the arrangement having a converter in a closed container, the container having a high voltage compartment and a low voltage compartment, wherein the high voltage compartment includes a transformer connected to a network to be supplied and the low voltage compartment includes the converter, the method comprising:
exchanging heat from the high voltage compartment to the low voltage compartment for heating the low voltage compartment with losses of the transformer.

17. The method according to claim 16, wherein the step of exchanging heat from the high voltage compartment comprises:
using a thermosyphon-type heat exchanger or a heat pipe, which is thermally connected to a surface of the transformer and which extends to the low voltage compartment for heating the low voltage compartment.

18. The method according to claim 16, wherein the low voltage compartment comprises controlled cooling means, the method comprising:
controlling the cooling means to keep the temperature of the converter at an elevated level for storing heat in the mechanical structure of the converter.

19. A converter arrangement, comprising:
a converter disposed in a closed container,
wherein the container includes a high voltage compartment and a low voltage compartment arranged to exchange heat therebetween, and
wherein the high voltage compartment has a transformer connectable to a network to be supplied and the low voltage compartment includes the converter.

20. The arrangement according to claim 19, comprising:
means for exchanging heat from the high voltage compartment to the low voltage compartment and for heating the low voltage compartment with losses of the transformer.
